(19) United States
(12) Patent Application Publication
(10) Pub. No.: US 2023/0139048 A1
(43) Pub. Date: May 4, 2023

(54) LIGHT-EMITTING DEVICE AND PROJECTOR

(71) Applicants: SOPHIA SCHOOL CORPORATION, Tokyo (JP); SEIKO EPSON CORPORATION, Tokyo (JP)

(72) Inventors: Shunsuke ISHIZAWA, TOKYO TO SHINJUKU KU (JP); Katsumi KISHINO, TOKYO TO AKIRUNO-SHI (JP)

(73) Assignees: SOPHIA SCHOOL CORPORATION, Tokyo (JP); SEIKO EPSON CORPORATION, Tokyo (JP)

(21) Appl. No.: 17/975,561

(22) Filed: Oct. 27, 2022

(30) Foreign Application Priority Data
Oct. 28, 2021 (JP) 2021-176376

(51) Int. Cl. G03B 21/20; H01S 5/42; H01S 5/042; H01S 5/11; H01S 5/183

(52) U.S. Cl. CPC G03B 21/2033; H01S 5/42; H01S 5/04256; H01S 5/04254; H01S 5/11; H01S 5/183

(57) ABSTRACT

A light-emitting device includes a substrate, a laminated structure having a plurality of column portions, and an electrode provided on a side of the laminated structure opposite to the substrate. Each of the plurality of column portions includes a light-emitting layer. The electrode is provided with a plurality of first holes. The plurality of column portions form a first photonic crystal. The electrode forms a second photonic crystal. The first photonic crystal and the second photonic crystal are optically coupled to each other.

The present application is based on, and claims priority from JP Application Serial Number 2021-176376, filed Oct. 28, 2021, the disclosure of which is hereby incorporated by reference herein in its entirety.

### BACKGROUND

### 1. Technical Field

The present disclosure relates to a light-emitting device and a projector.

### 2. Related Art

Semiconductor lasers are promising next-generation light sources having high luminance. In particular, semiconductor lasers to which nano-columns are applied are expected to be able to realize high-power light emission at a narrow radiation angle due to an effect of a photonic crystal derived from the nano-columns.

For example, JP-A-2021-7136 describes a light-emitting device including a plurality of column portions having a light-emitting layer and an electrode provided on the plurality of column portions. According to the description, by providing a plurality of holes in the electrode, light absorption can be reduced in proportion to the holes.

When a hole is provided in an electrode as described above, it is desired that light generated by a light-emitting layer does not scatter by the hole. When the light is scattered by the hole, the light loss increases.

### SUMMARY

One aspect of the light-emitting device according to the present disclosure includes

a substrate,

a laminated structure having a plurality of column portions, and

an electrode provided on a side of the laminated structure opposite to the substrate, wherein

each of the plurality of column portions includes a light-emitting layer,

the electrode is provided with a plurality of first holes,

the plurality of column portions form a first photonic crystal,

the electrode forms a second photonic crystal, and

the first photonic crystal and the second photonic crystal are optically coupled to each other.

One aspect of the projector according to the present disclosure includes one aspect of the light-emitting device.

### BRIEF DESCRIPTION OF THE DRAWINGS

FIG. 1 is a cross-sectional view schematically illustrating a light-emitting device according to the present embodiment.

FIG. 2 is a plan view schematically illustrating column portions and first holes of a light-emitting device according to the present embodiment.

FIG. 3 is a cross-sectional view schematically illustrating a step of producing a light-emitting device according to the present embodiment.

FIG. 4 is a cross-sectional view schematically illustrating a step of producing a light-emitting device according to the present embodiment.

FIG. 5 is a cross-sectional view schematically illustrating a step of producing a light-emitting device according to the present embodiment.

FIG. 6 is a cross-sectional view schematically illustrating a light-emitting device according to a first variation of the present embodiment.

FIG. 7 is a plan view schematically illustrating column portions and first holes of a light-emitting device according to the first variation of the present embodiment.

FIG. 8 is a plan view schematically illustrating column portions and first holes of a light-emitting device according to the first variation of the present embodiment.

FIG. 9 is a cross-sectional view schematically illustrating a light-emitting device according to a second variation of the present embodiment.

FIG. 10 is a plan view schematically illustrating column portions and first holes of a light-emitting device according to a third variation of the present embodiment.

FIG. 11 is a plan view schematically illustrating column portions and first holes of a light-emitting device according to the third variation of the present embodiment.

FIG. 12 is a plan view schematically illustrating column portions and first holes of a light-emitting device according to the third variation of the present embodiment.

FIG. 13 is a cross-sectional view schematically illustrating a light-emitting device according to a fourth variation of the present embodiment.

FIG. 14 is a cross-sectional view schematically illustrating a light-emitting device according to a fifth variation of the present embodiment.

FIG. 15 is a plan view schematically illustrating column portions, a second electrode, and first holes of a light-emitting device according to the fifth variation of the present embodiment.

FIG. 16 is a cross-sectional view schematically illustrating a light-emitting device according to a sixth variation of the present embodiment.

FIG. 17 is a diagram schematically illustrating a projector according to the present embodiment.

### DESCRIPTION OF EXEMPLARY EMBODIMENTS

Hereinafter, preferred embodiments of the present disclosure will be described in detail with reference to the drawings. Note that the embodiments described hereinafter is not intended to unreasonably limit the content of the present disclosure as set forth in the claims. In addition, not all of the configurations described below are essential constituent requirements of the present disclosure.

### 1. Light-Emitting Device

### 1.1. Overall Configuration

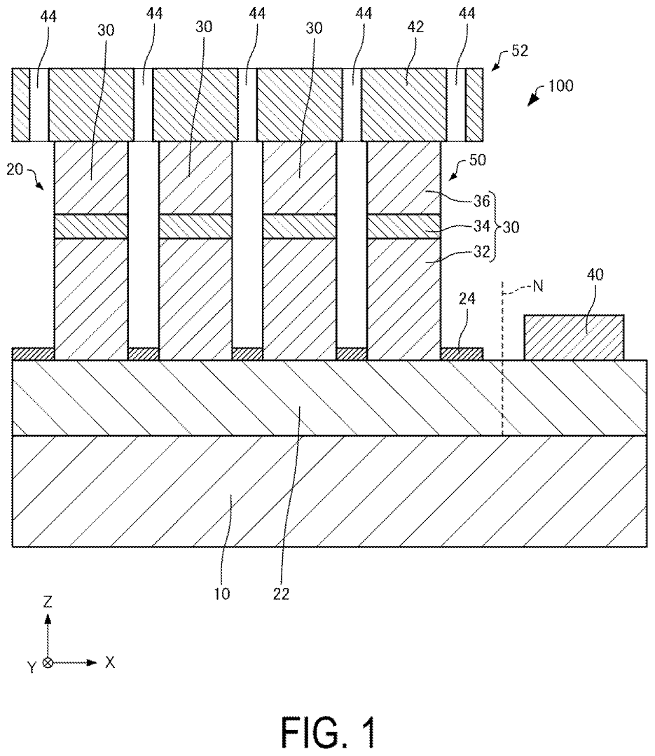

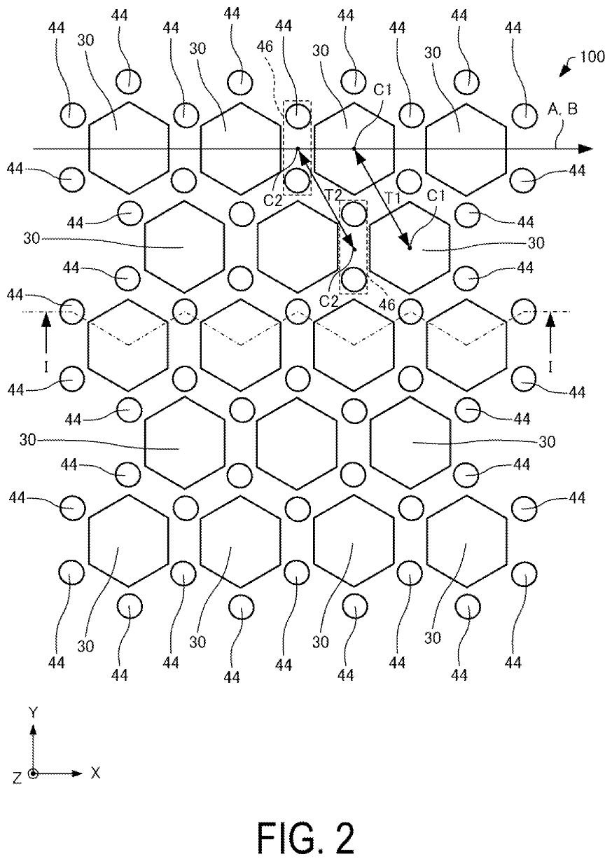

First, a light-emitting device according to the present embodiment will be described with reference to the drawings. FIG. 1 is a cross-sectional view schematically illustrating a light-emitting device 100 according to the present embodiment. FIG. 2 is a plan view schematically illustrating the light-emitting device 100 according to the present embodiment. Note that FIG. 1 is a cross-sectional view taken along a line I-I in FIG. 2. Further, in FIG. 1 and FIG. 2, the X-axis, the Y-axis, and the Z-axis are shown as three axes orthogonal to each other.

As illustrated in FIG. 1, the light-emitting device 100 includes, for example, a substrate 10, a laminated structure 20, a first electrode 40, and a second electrode 42. The light-emitting device 100 is, for example, a semiconductor laser.

The substrate 10 is, for example, a Si substrate, a GaN substrate, a sapphire substrate, or a SiC substrate.

The laminated structure 20 is provided at the substrate 10. In the illustrated example, the laminated structure 20 is provided on the substrate 10. The laminated structure 20 includes, for example, a buffer layer 22 and a plurality of column portions 30. Note that for convenience, members in addition to the column portions 30 are not illustrated in FIG. 2.

In the present specification, when a light-emitting layer 34 of the column portion 30 is used as a reference along a lamination direction of the laminated structure 20 (hereinafter, also simply referred to as “lamination direction”), the direction from the light-emitting layer 34 toward a second semiconductor layer 36 of the column portion 30 is referred to as “upward”, and the direction from the light-emitting layer 34 toward a first semiconductor layer 32 of the column portion 30 is referred to as “downward”. A direction orthogonal to the lamination direction is referred to as “in-plane direction”. Additionally, the phrase “lamination direction of laminated structure 20” refers to the lamination direction of the first semiconductor layer 32 and the light-emitting layer 34, which is the direction of a vertical line N to the substrate 10. Specifically, the phrase “vertical line N to substrate 10” refers to a line on the upper surface of the substrate 10. In the illustrated example, the lamination direction is the Z-axis direction.

The buffer layer 22 is provided on the substrate 10. The buffer layer 22 is, for example, an n-type GaN layer doped with Si. A mask layer 24 for growing the column portions 30 is provided on the buffer layer 22. The mask layer 24 is, for example, a titanium layer, a silicon oxide layer, a titanium oxide layer, or an aluminum oxide layer.

The column portions 30 are provided on the buffer layer 22. The column portions 30 have a columnar shape protruding upward from the buffer layer 22. In other words, the column portions 30 protrude upward from the substrate 10 with the buffer layer 22 interposed therebetween. The column portions 30 are also referred to as, for example, nano-columns, nano-wires, nano-rods, or nano-pillars. A planar shape of the column portion 30 is, for example, a polygon such as a hexagon, or a circle. In the example illustrated in FIG. 2, the planar shape of the column portion 30 is a regular hexagon.

A diameter of the column portion 30 is, for example, from 50 nm to 500 nm. By setting the diameter of the column portion 30 to be 500 nm or less, a light-emitting layer 34 of high quality crystals can be obtained, and a distortion inherent in the light-emitting layer 34 can be reduced. This makes it possible to amplify light generated in the light-emitting layer 34 with high efficiency.

Note that, when the planar shape of the column portion 30 is a circle, the phrase “diameter of column portion 30” refers to the diameter of the circle, and when the planar shape of the column portion 30 is not a circle, the phrase “diameter of column portion 30” refers to the diameter of the smallest circle containing the planar shape of the column portion 30. For example, when the planar shape of the column portion 30 is a polygon, the diameter of the column portion 30 is the diameter of the smallest circle containing the polygon, and when the plane shape of the column portion 30 is an ellipse, the diameter of the column portion 30 is the diameter of the smallest circle containing the ellipse. The same applies to the “diameter of first hole 44” described later.

The column portion 30 is provided in plurality. The spacing between adjacent column portions 30 is, for example, from 1 nm to 500 nm. The plurality of column portions 30 are arranged in a predetermined direction at a predetermined period T1 when viewed from the lamination direction. The plurality of column portions 30 are arranged in, for example, a triangular lattice, or a square lattice. In the example illustrated in FIG. 2, the plurality of column portions 30 are arranged in a regular, triangular lattice. The plurality of column portions 30 can develop the effect of photonic crystal.

Note that the phrase “period T1 of column portions 30” refers to a distance between centers C1 of the column portions 30 adjacent to each other in a predetermined direction. When the planar shape of the column portion 30 is a circle, the phrase “center C1 of column portion 30” refers to the center of the circle, and when the planar shape of the column portion 30 is not a circle, the phrase “center C1 of column portion 30” refers to the center of the smallest circle containing the planar shape of the column portion 30. For example, when the planar shape of the column portion 30 is a polygon, the center C1 of the column portion 30 is the center of the smallest circle containing the polygon, and when the plane shape of the column portion 30 is an ellipse, the center C1 of the column portion 30 is the center of the smallest circle containing the ellipse.

As illustrated in FIG. 1, the column portion 30 includes, for example, the first semiconductor layer 32, the light-emitting layer 34, and the second semiconductor layer 36.

The first semiconductor layer 32 is provided on the buffer layer 22. The first semiconductor layer 32 is provided between the substrate 10 and the light-emitting layer 34. The first semiconductor layer 32 is a first conductive type semiconductor layer. The first semiconductor layer 32 is, for example, an n-type GaN layer doped with Si.

The light-emitting layer 34 is provided between the first semiconductor layer 32 and the second semiconductor layer 36. The light-emitting layer 34 generates light when an electric current is injected. The light-emitting layer 34 includes, for example, a well layer and a barrier layer. The well layer and the barrier layer are i-type semiconductor layers that are not intentionally doped with impurities. The well layer is, for example, an InGaN layer. The barrier layer is, for example, a GaN layer. The light-emitting layer 34 has a Multiple Quantum Well (MQW) structure including the well layer and the barrier layer.

Note that the numbers of the well layers and the barrier layers constituting the light-emitting layer 34 are not limited. For example, only one layer of the well layer may be provided, in which case the light-emitting layer 34 has a Single Quantum Well (SQW) structure.

The second semiconductor layer 36 is provided on the light-emitting layer 34. The second semiconductor layer 36 is provided between the light-emitting layer 34 and the second electrode 42. The second semiconductor layer 36 is a second conductive type semiconductor layer different from the first conductive type. The second semiconductor layer 36 is, for example, a p-type GaN layer doped with Mg. The first semiconductor layer 32 and the second semiconductor layer 36 are cladding layers having a function of confining light to the light-emitting layer 34.

Note that, although not illustrated, an Optical Confinement Layer (OCL) including an i-type InGaN layer and a GaN layer may be provided either between the first semiconductor layer 32 and the light-emitting layer 34 or between the light-emitting layer 34 and the second semiconductor layer 36, or both between the first semiconductor layer 32 and the light-emitting layer 34 and between the light-emitting layer 34 and the second semiconductor layer 36. Additionally, the second semiconductor layer 36 may have an Electron Blocking Layer (EBL) including a p-type AlGaN layer.

The first electrode 40 is provided on the buffer layer 22. The buffer layer 22 may be in ohmic contact with the first electrode 40. The first electrode 40 is electrically coupled to the first semiconductor layer 32. In the illustrated example, the first electrode 40 is electrically coupled to the first semiconductor layer 32 via the buffer layer 22. The first electrode 40 is one electrode for injecting an electric current into the light-emitting layer 34. The first electrode 40 that may be used is, for example, one obtained by stacking a Cr layer, an Ni layer, and an Au layer in this order from the buffer layer 22 side.

The second electrode 42 is provided on a side of the laminated structure 20 opposite to the substrate 10. The second electrode 42 is provided on the second semiconductor layer 36. The second semiconductor layer 36 may be in ohmic contact with the second electrode 42. The second electrode 42 is another electrode for injecting an electric current into the light-emitting layer 34. The second electrode 42 that may be used is, for example, Indium Tin Oxide (ITO) or the like.

Note that, although the description above is about a InGaN-based light-emitting layer 34, various types of material capable of emitting light when an electric current is injected can be used in the light-emitting layer 34 in accordance with the wavelength of light emitted. For example, AlGaN-based, AlGaAs-based, InGaAs-based, InGaAsP-based, InP-based, GaP-based, or AlGaP-based semiconductor materials can be used in the light-emitting layer 34.

### 1.2. First Photonic Crystal and Second Photonic Crystal

The plurality of column portions 30 forms a first photonic crystal 50. In the example illustrated in FIG. 1, the first photonic crystal 50 includes the plurality of column portions 30 and gaps between adjacent column portions 30.

A plurality of first holes 44 are provided in the second electrode 42. The first holes 44 extend through the second electrode 42, for example. In the illustrated example, the first holes 44 extend through the second electrode 42 in the lamination direction. The first holes 44 are through holes. In the illustrated example, the first holes 44 are gaps. Note that, although not illustrated, the first holes 44 may be filled with a member having a refractive index lower than that of the second electrode 42. In the example illustrated in FIG. 2, a planar shape of the first hole 44 is a circle. Note that the shape of the first hole 44 may be an ellipse, or may be a polygon. In the example illustrated in FIG. 2, the plurality of first holes 44 have the same size as each other.

In the example illustrated in FIG. 2, a diameter of the first hole 44 is smaller than the diameter of the column portion 30. The diameter of the first hole 44 is less than or equal to the period T1 of the column portions 30. The diameter of the first hole 44 is less than or equal to a wavelength of light generated by the light-emitting layer 34. A distance between adjacent first holes 44 is less than or equal to the wavelength of light generated by the light-emitting layer 34.

The first holes 44 do not overlap with the column portions 30 when viewed from the lamination direction. The outer edges of the first holes 44 do not intersect the outer edges of the column portions 30 when viewed from the lamination direction. In the illustrated example, six first holes 44 are provided at equal intervals surrounding one column portion 30.

As illustrated in FIG. 2, two first holes 44 adjacent to each other in the Y-axis direction constitute one first hole group 46. In the illustrated example, the plurality of first hole groups 46 is arranged in a regular, triangular lattice. A period T2 of the first hole groups 46 is the same as the period T1 of the column portions 30.

Note that the phrase “period T2 of first hole groups 46” refers to a distance between centers C2 of the first hole groups 46 adjacent to each other in a predetermined direction. The phrase “center C2 of first hole group 46” refers to the center of the smallest circle containing two first holes 44 constituting one first hole group 46. In the illustrated example, the phrase “center C2 of first hole group 46” is the midpoint of a line segment connecting the center of one of the two first holes 44 constituting one first hole group 46 and the center of the other first hole 44 constituting the first hole group 46.

The second electrode 42 forms a second photonic crystal 52. In the example illustrated in FIG. 1, the second photonic crystal 52 includes the second electrode 42 and the plurality of first holes 44 provided in the second electrode 42.

The first photonic crystal 50 and the second photonic crystal 52 are optically coupled. Here, the phrase “the first photonic crystal 50 and the second photonic crystal 52 are optically coupled” refers to a state in which the first photonic crystal 50 and the second photonic crystal 52 are affected by each other, meaning a state in which the effect of one photonic crystal is developed by the first photonic crystal 50 and the second photonic crystal 52. When the first photonic crystal 50 and the second photonic crystal 52 are optically coupled to each other, a waveguide mode in the first photonic crystal 50 and a waveguide mode in the second photonic crystal 52 are combined with each other. In other words, in the first photonic crystal 50 and the second photonic crystal 52, a laser oscillation in the same oscillation mode can be obtained. In the light-emitting device 100, the first photonic crystal 50 and the second photonic crystal 52 are optically coupled to each other to form an optical confinement mode.

The first photonic crystal 50 and the second photonic crystal 52 have a lattice arrangement of the same type, for example, and are arranged at the same period. The first photonic crystal 50 and the second photonic crystal 52 have the same in-plane arrangement orientation as each other, for example. As such, in the light-emitting device 100, the first photonic crystal 50 and the second photonic crystal 52 can be optically coupled, and scattering of light in the first holes 44 can be reduced.

In the illustrated example, both the plurality of column portions 30 constituting the first photonic crystal 50 and the plurality of first hole groups 46 constituting the second photonic crystal 52 are arranged in a regular, triangular lattice. Furthermore, the period T1 of the plurality of column portions 30 constituting the first photonic crystal 50 is the same as the period T2 of the plurality of first hole groups 46 constituting the second photonic crystal 52.

An in-plane arrangement orientation A of the plurality of column portions 30 constituting the first photonic crystal 50 aligns with an in-plane arrangement orientation B of the plurality of first hole groups 46 constituting the second photonic crystal 52. The in-plane arrangement orientation A of the plurality of column portions 30 is a direction in which the column portions 30 are lined up in a plan view. The in-plane arrangement orientation B of the plurality of first hole groups 46 is a direction in which the first hole groups 46 are lined up in a plan view. The phrase “the arrangement orientation A aligns with the arrangement orientation B” refers to a state in which a direction of a predetermined row of the column portions 30 aligns with a direction of a row of the first hole groups 46 corresponding to the predetermined row of the column portions 30, meaning a state in which no rotational shift exists between a row of the column portions 30 and a row of the first hole groups 46 corresponding to the row of the column portions 30.

As described above, in the light-emitting device 100, the plurality of column portions 30 and the plurality of first hole groups 46 have the same type of lattice arrangement, have the same period, and have in-plane arrangement orientations that are aligned. As such, the first photonic crystal 50 and the second photonic crystal 52 have the same type of lattice arrangement, have the same period, and have in-plane arrangement orientations that are aligned.

In the light-emitting device 100, the first photonic crystal 50 and the second photonic crystal 52 have a constant relative positional relationship between the two photonic crystals in the plane. As such, the first photonic crystal 50 and the second photonic crystal 52 can be optically coupled to develop the effect of one photonic crystal. For example, in a case in which the relative positional relationship between the two photonic crystals is not constant and a position shift occurs, a photonic band varies due to the position shift; as such, an ideal optical confinement effect cannot be obtained because, for example, laser oscillation in a single mode cannot be obtained.

Note that the configurations of the first photonic crystal 50 and the second photonic crystal 52 are not limited to the above example, provided that the configurations allow the first photonic crystal 50 and the second photonic crystal 52 to be optically coupled and facilitate the effect of reducing light scattering in the first holes 44.

In the light-emitting device 100, the p-type second semiconductor layer 36, the i-type light-emitting layer 34 not intentionally doped with impurities, and the n-type first semiconductor layer 32 constitute a pin diode. In the light-emitting device 100, when a forward bias voltage of a pin diode is applied between the first electrode 40 and the second electrode 42, an electric current is injected into the light-emitting layer 34, and recombination of electrons and holes occurs in the light-emitting layer 34. This recombination causes light emission. The light generated in the light-emitting layer 34 propagates in an in-plane direction through the first semiconductor layer 32 and the second semiconductor layer 36, forms a standing wave due to the effect of the first photonic crystal 50 and the second photonic crystal 52 that are optically coupled to each other, and receives a gain in the light-emitting layer 34 to generate laser oscillation. Then, the light-emitting device 100 emits +first order diffracted light and −first order diffracted light as laser light in the lamination direction.

Note that, although not illustrated, a reflection layer may be provided between the substrate 10 and the buffer layer 22, or below the substrate 10. The reflective layer is, for example, a Distributed Bragg Reflector (DBR) layer. The reflective layer can reflect light generated at the light-emitting layer 34, allowing the light-emitting device 100 to emit light only from the second electrode 42 side.

### 1.3. Functions and Advantages

In the light-emitting device 100, each of the plurality of column portions 30 includes a light-emitting layer 34. The second electrode 42 is provided with the plurality of first holes 44. The plurality of column portions 30 forms the first photonic crystal 50. The second electrode 42 forms the second photonic crystal 52. The first photonic crystal 50 and the second photonic crystal 52 are optically coupled to each other. In the light-emitting device 100, the first photonic crystal 50 and the second photonic crystal 52 are coupled to develop the effect of one photonic crystal; as such, scattering of light generated by the light-emitting layer 34 in the first holes 44 can be reduced.

In the light-emitting device 100, each of the plurality of first holes 44 extends through the second electrode 42. As such, in the light-emitting device 100, the portion of the light-emitting device 100 with the second electrode 42 provided can have a smaller average refractive index in an in-plane direction when compared to a case in which the first holes do not extend through the second electrode. This can increase the optical confinement factor.

In the light-emitting device 100, each of the plurality of first holes 44 does not overlap with the plurality of column portions 30 when viewed from the lamination direction. As such, in the light-emitting device 100, when the first holes 44 are formed by etching, damage to the column portions 30 caused by etching can be suppressed.

### 2. Method of Producing Light-Emitting Device

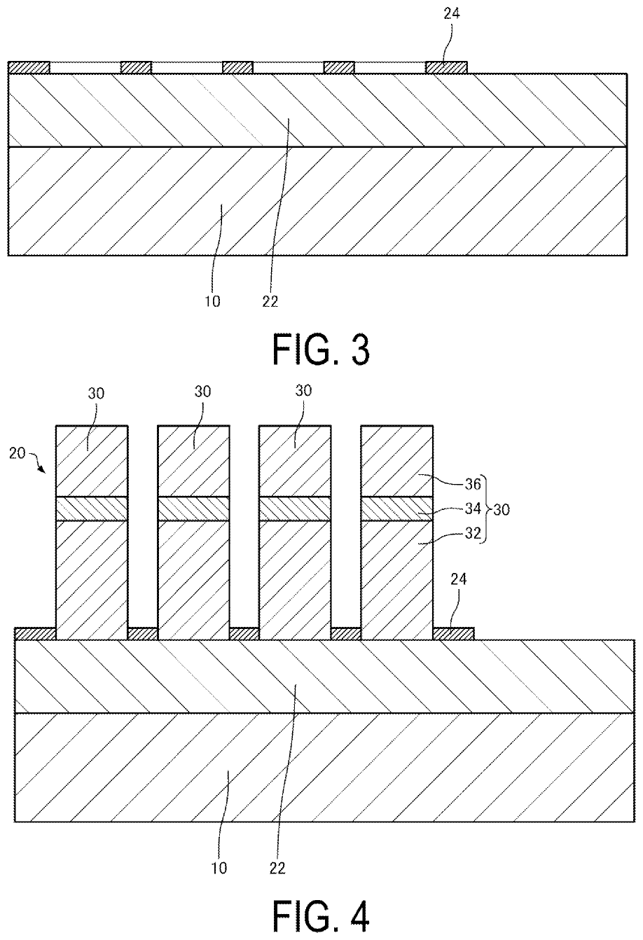

Next, a method of producing the light-emitting device 100 according to the present embodiment will be described with reference to drawings. FIG. 3 to FIG. 5 are cross-sectional views schematically illustrating steps of producing the light-emitting device 100 according to the present embodiment.

As illustrated in FIG. 3, the buffer layer 22 is epitaxially grown on the substrate 10. Examples of the method for epitaxial growth include Metal Organic Chemical Vapor

Deposition (MOCVD) and Molecular Beam Epitaxy (MBE).

Next, the mask layer 24 is formed on the buffer layer 22. The mask layer 24 is formed by, for example, film formation by electron-beam vapor deposition or sputtering, and patterning. Patterning is performed, for example, by electron-beam lithography and dry etching.

As shown in FIG. 4, the first semiconductor layer 32, the light-emitting layer 34, and the second semiconductor layer 36 are epitaxially grown in this order on the buffer layer 22 by using the mask layer 24 as a mask. Examples of the method for epitaxial growth include MOCVD and MBE. The present step can form a plurality of column portions 30.

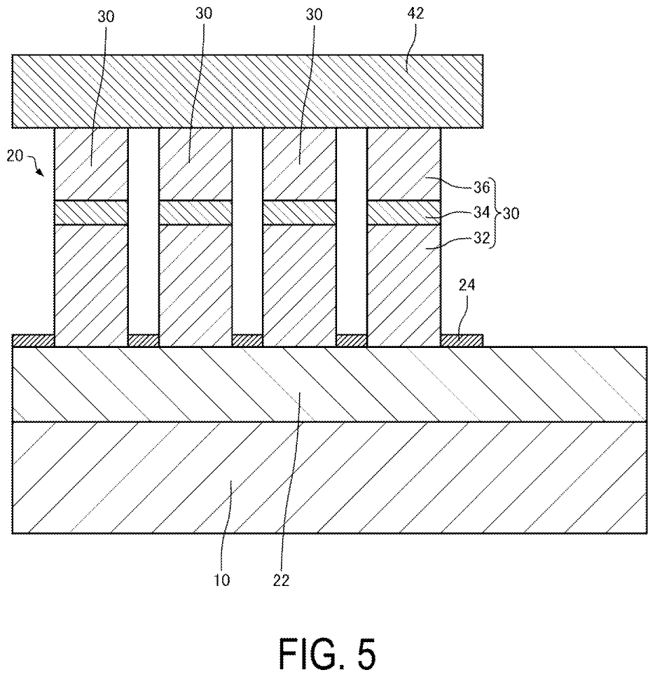

As illustrated in FIG. 5, the second electrode 42 is formed on the second semiconductor layer 36. The second electrode 42 is formed, for example, by sputtering, or vacuum vapor deposition. In the step of forming the second electrode 42, oblique vapor deposition may be performed so that a material of electrode does not adhere to a side surface of the column portions 30.

As illustrated in FIG. 1, the second electrode 42 is patterned to form the plurality of first holes 44. Patterning is performed, for example, by electron-beam lithography and dry etching.

Next, the first electrode 40 is formed on the buffer layer 22. The first electrode 40 is formed, for example, by sputtering, or vacuum vapor deposition. Note that the order of the step of forming the first electrode 40 and the step of forming the second electrode 42 are not limited.

The light-emitting device 100 can be produced by the above steps.

### 3. Variations of Light-Emitting Device

### 3.1. First Modified Example

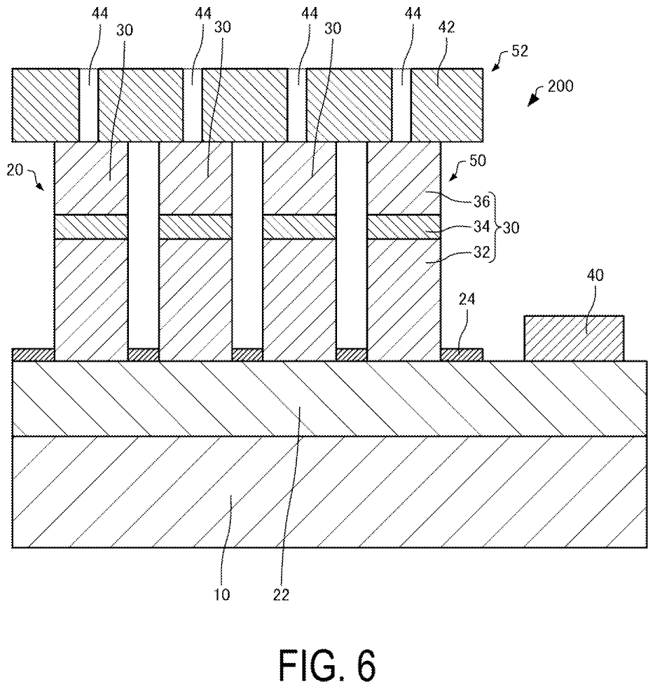

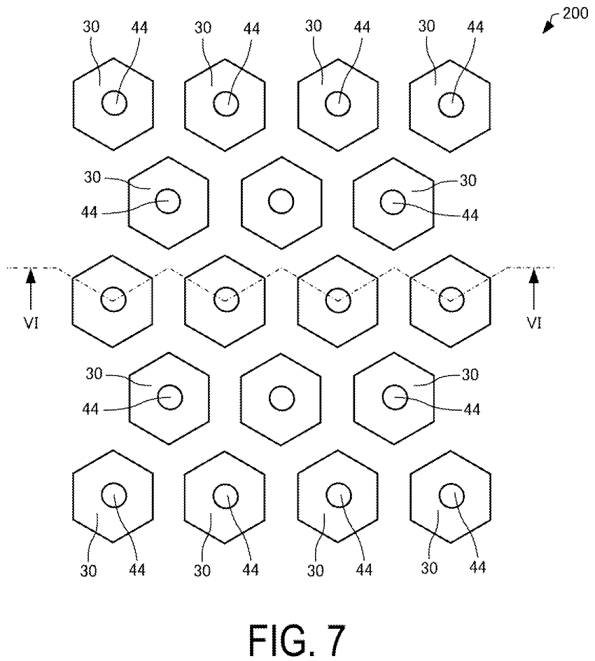

Next, a light-emitting device 200 according to a first variation of the present embodiment will be described with reference to drawings. FIG. 6 is a cross-sectional view schematically illustrating the light-emitting device 200 according to the first variation of the present embodiment. FIG. 7 is a plan view schematically illustrating column portions 30 and first holes 44 of the light-emitting device 200 according to the first variation of the present embodiment. Note that FIG. 6 is a cross-sectional view taken along a line VI-VI in FIG. 7.

Hereinafter, members of the light-emitting device 200 according to the first variation of the present embodiment having the same functions as the components of the light-emitting device 100 according to the present embodiment described above will be denoted by the same reference numerals, and detailed description of such members will be omitted. The same applies to the light-emitting devices according to second to sixth variations of the present embodiment to be described below.

As illustrated in FIG. 1 and FIG. 2, in the light-emitting device 100 described above, the first holes 44 do not overlap with the column portions 30 when viewed from the lamination direction.

In contrast, as illustrated in FIG. 6 and FIG. 7, in the light-emitting device 200, the first holes 44 overlap with the column portions 30 when viewed from the lamination direction. The outer edges of the first holes 44 are located inside the outer edges of the column portions 30. In the illustrated example, all of the first holes 44 overlap with the column portions 30 when viewed from the lamination direction. The centers of the first holes 44 and the centers of the column portions 30 are, for example, aligned.

In the example illustrated in FIG. 6, both the plurality of column portions 30 constituting the first photonic crystal 50 and the plurality of first holes 44 constituting the second photonic crystal 52 are arranged in a regular, triangular lattice. Furthermore, the period of the plurality of column portions 30 constituting the first photonic crystal 50 is the same as the period of the plurality of first holes 44 constituting the second photonic crystal 52. Furthermore, an in-plane arrangement orientation of the plurality of column portions 30 constituting the first photonic crystal 50 aligns with an in-plane arrangement orientation of the plurality of first holes 44 constituting the second photonic crystal 52. As such, in the light-emitting device 200, the first photonic crystal 50 and the second photonic crystal 52 can be optically coupled.

In the light-emitting device 200, each of the plurality of first holes 44 overlaps with each of the plurality of column portions 30 when viewed from the lamination direction. As such, compared with a case in which, for example, the first holes do not overlap with the column portions, the light-emitting device 200 can have a lower refractive index directly above the light-emitting layer 34 in which light is easily confined; accordingly, the optical confinement factor can be increased.

The first holes 44 of the light-emitting device 200 are formed by, for example, wet-etching the second electrode 42. As such, compared to a case in which the first holes 44 are etched by dry etching, damage to the column portions 30 caused by etching can be reduced.

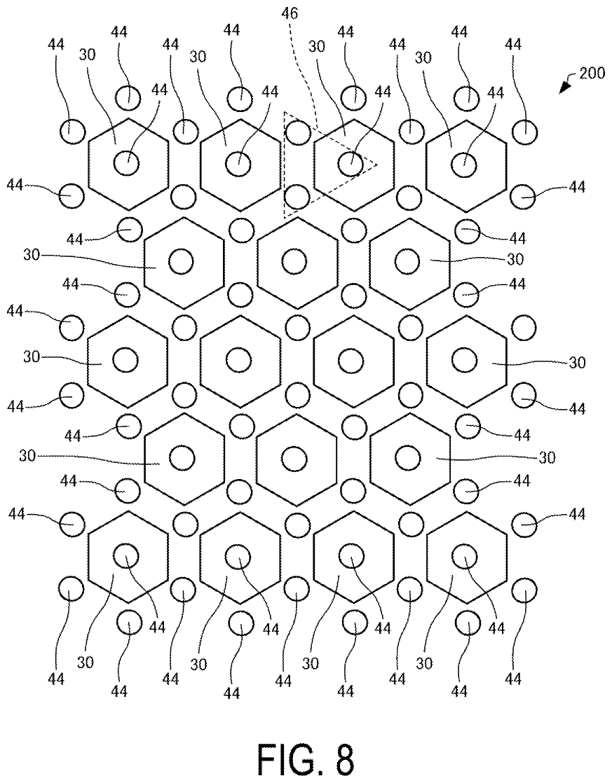

Note that as illustrated in FIG. 8, the light-emitting device 200 may be provided with first holes 44 overlapping with the column portions 30 and first holes 44 not overlapping with the column portions 30 when viewed from the lamination direction. In the example illustrated in FIG. 8, the plurality of first holes 44 have an arrangement that is a combination of the arrangement of the first holes 44 illustrated in FIG. 2 and the arrangement of the first holes 44 illustrated in FIG. 7.

In the example illustrated in FIG. 8, a first hole 44 overlapping with the column portion 30 and two first holes 44 constitute one first hole group 46; the two first holes 44 are located in the −X-axis direction of the first hole 44 overlapping with the column portion 30, and are adjacent to the first hole 44 overlapping with the column portion 30 while being adjacent to each other in the Y-axis direction. In the example illustrated in FIG. 8, for example, the portion of the light-emitting device 200 with the second electrode 42 provided can have a reduced average refractive index in an in-plane direction when compared to the example illustrated in FIG. 2 and the example illustrated in FIG. 7.

In the example illustrated in FIG. 8, both the plurality of column portions 30 constituting the first photonic crystal 50 and the plurality of first hole groups 46 constituting the second photonic crystal 52 are arranged in a regular, triangular lattice. Furthermore, the period of the plurality of column portions 30 constituting the first photonic crystal 50 is the same as the period of the plurality of first hole groups 46 constituting the second photonic crystal 52. Furthermore, an in-plane arrangement orientation of the plurality of column portions 30 constituting the first photonic crystal 50 aligns with an in-plane arrangement orientation of the plurality of first hole groups 46 constituting the second photonic crystal 52. As such, the first photonic crystal 50 and the second photonic crystal 52 can be optically coupled.

### 3.2. Second Modified Example

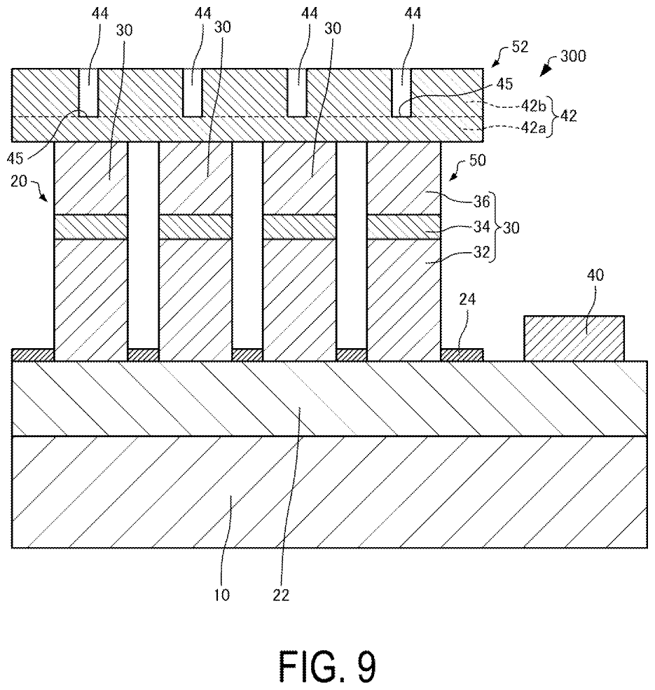

Next, a light-emitting device 300 according to a second variation of the present embodiment will be described with reference to drawings. FIG. 9 is a cross-sectional view schematically illustrating the light-emitting device 300 according to the second variation of the present embodiment.

As illustrated in FIG. 1, in the light-emitting device 100 described above, the first holes 44 extend through the second electrode 42.

In contrast, as illustrated in FIG. 9, in the light-emitting device 300, first holes 44 do not extend through a second electrode 42. The first holes 44 are bottomed holes. Furthermore, in the light-emitting device 300, similar to the light-emitting device 200 illustrated in FIG. 6 and FIG. 7, the first holes 44 overlap with column portions 30 when viewed from the lamination direction.

The second electrode 42 includes a first layer 42a not provided with the first holes 44 and a second layer 42b provided with the first holes 44. The first layer 42a is provided on a plurality of column portions 30. The first layer 42a defines bottom surfaces 45 of the first holes 44. The first layer 42a is provided between the plurality of column portions 30 and the second layer 42b. The second layer 42b is provided on the first layer 42a. The first holes 44 may be formed by dry etching, or may be formed by wet etching.

An optical distance between a first photonic crystal 50 and a second photonic crystal 52 is 3λ or less. Note that λ is an oscillation wavelength. The optical distance is a so-called optical path length, and is obtained by multiplying propagation distance of light by refractive index. By arranging the first photonic crystal 50 and the second photonic crystal 52 at a distance of 3λ or less, the first photonic crystal 50 and the second photonic crystal 52 can be optically coupled tightly. In the illustrated example, the optical distance between the first photonic crystal 50 and the second photonic crystal 52 can be calculated from the thickness of the first layer 42a and the refractive index of the first layer 42a.

In the light-emitting device 300, each of the plurality of first holes 44 does not extend through the second electrode 42. As such, in the light-emitting device 300, damage to the column portions 30 caused by the etching for forming the first holes 44 can be suppressed.

### 3.3. Third Modified Example

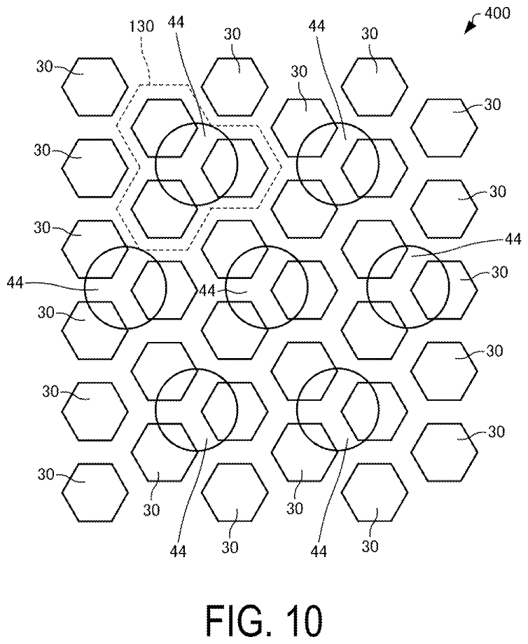

Next, a light-emitting device 400 according to a third variation of the present embodiment will be described with reference to drawings. FIG. 10 is a plan view schematically illustrating column portions 30 and first holes 44 of the light-emitting device 400 according to the third variation of the present embodiment.

As illustrated in FIG. 2, in the light-emitting device 100 described above, the first holes 44 do not overlap with the column portions 30 when viewed from the lamination direction.

In contrast, as illustrated in FIG. 10, in the light-emitting device 400, the first holes 44 overlap with multiple column portions 30 when viewed from the lamination direction. In the illustrated example, one first hole 44 overlaps with three column portions 30 when viewed from the lamination direction. The plurality of first holes 44 are arranged in a regular, triangular lattice. The first holes 44 are formed, for example, by wet-etching the second electrode 42.

The three column portions 30 overlapping with the one first hole 44 constitute a column portion group 130. Both the plurality of column portion groups 130 constituting the first photonic crystal 50 and the plurality of first holes 44 constituting the second photonic crystal 52 are arranged in a regular, triangular lattice. Furthermore, the period of the plurality of column portion groups 130 constituting the first photonic crystal 50 is the same as the period of the plurality of first holes 44 constituting the second photonic crystal 52. Furthermore, an in-plane arrangement orientation of the plurality of column portion groups 130 constituting the first photonic crystal 50 aligns with an in-plane arrangement orientation B of the plurality of first holes 44 constituting the second photonic crystal 52. As such, in the light-emitting device 400, the first photonic crystal 50 and the second photonic crystal 52 can be optically coupled.

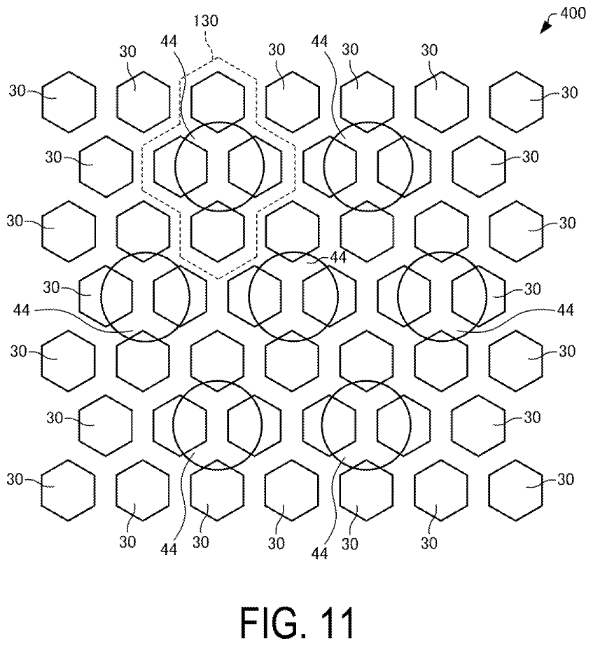

Note that the number of column portions 30 overlapping with the first holes 44 when viewed from the lamination direction is not limited, provided that the first photonic crystal 50 and the second photonic crystal 52 can be optically coupled. For example, as illustrated in FIG. 11, one first hole 44 may overlap with four column portions 30. The four column portions 30 overlapping with the one first hole 44 constitute one column portion group 130.

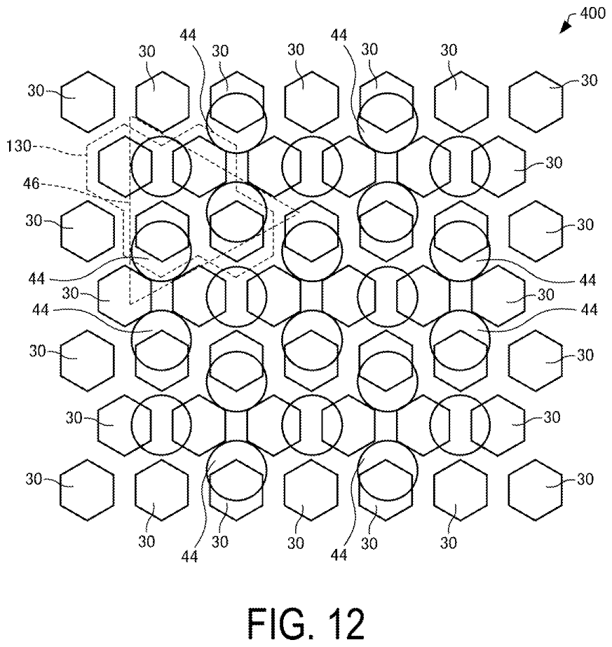

For example, as illustrated in FIG. 12, a first hole group 46 including three first holes 44 may overlap with a column portion group 130 including four column portions 30 when viewed from the lamination direction. Both the plurality of column portion groups 130 constituting the first photonic crystal 50 and the plurality of first hole groups 46 constituting the second photonic crystal 52 are arranged in a regular, triangular lattice. Furthermore, the period of the plurality of column portion groups 130 constituting the first photonic crystal 50 is the same as the period of the plurality of first hole groups 46 constituting the second photonic crystal 52. Furthermore, an in-plane arrangement orientation of the plurality of column portion groups 130 constituting the first photonic crystal 50 aligns with an in-plane arrangement orientation B of the plurality of first hole groups 46 constituting the second photonic crystal 52. As such, the first photonic crystal 50 and the second photonic crystal 52 can be optically coupled.

### 3.4. Fourth Variation

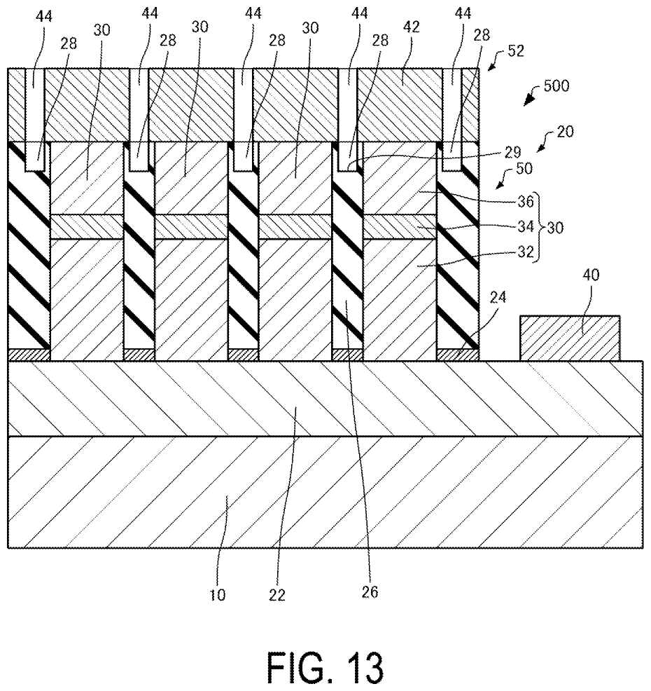

Next, a light-emitting device 500 according to a fourth variation of the present embodiment will be described with reference to drawings. FIG. 13 is a cross-sectional view schematically illustrating the light-emitting device 500 according to the fourth variation of the present embodiment.

As illustrated in FIG. 1, in the light-emitting device 100 described above, a gap is provided between adjacent column portions 30.

In contrast, as illustrated in FIG. 13, in the light-emitting device 500, a laminated structure 20 includes a light propagation layer 26 provided between adjacent column portions.

The light propagation layer 26 is provided on a mask layer 24. The light propagation layer 26 is made of, for example, a dielectric material. Specifically, the light propagation layer 26 is a silicon oxide layer. More specifically, the light propagation layer 26 is a SiO₂ layer. Light generated by a light-emitting layer 34 propagates in the light propagation layer 26 in an in-plane direction. A first photonic crystal 50 includes a plurality of column portions 30 and the light propagation layer 26 between adjacent column portions 30.

A second hole 28 is provided in the light propagation layer 26. The second hole 28 is coupled with a first hole 44. The second hole 28 is provided in plurality. The number of the second holes 28 is, for example, the same as the number of the first holes 44. A bottom surface 29 of the second hole 28 is provided between the second semiconductor layers 36 of adjacent column portions 30. The second hole 28 is not provided between the light-emitting layers 34 of adjacent column portions 30. The second holes 28 do not extend all the way to the light-emitting layer 34 in the lamination direction. The bottom surface 29 is defined by the second semiconductor layer 36. In the illustrated example, the second holes 28 are gaps. Note that, although not illustrated, the second holes 28 may be filled with a member having a refractive index lower than that of the light propagation layer 26. Further, the second holes 28 may not be provided.

The light propagation layer 26 is formed by, for example, a CVD (Chemical Vapor Deposition) method, or a spin-coating method. The second holes 28 are formed by patterning the light propagation layer 26. The second holes 28 are formed, for example, continued from the first holes 44.

In the light-emitting device 500, the laminated structure 20 includes the light propagation layer 26 provided between adjacent column portions 30 of the plurality of column portions 30. The light propagation layer 26 is provided with the second hole 28. The second hole 28 is coupled with one of the plurality of first holes 44. The bottom surface 29 of the second hole 28 is positioned between the second semiconductor layers 36 of adjacent column portions 30 of the plurality of column portions 30. As such, in the light-emitting device 500, the portion of the light-emitting device 500 with the second holes 28 provided can have a smaller average refractive index in an in-plane direction when compared to a case in which the second hole is not provided. This can increase the optical confinement factor. Furthermore, since the light propagation layer 26 is provided between adjacent column portions 30, adherence of a material of electrode to a side surface of the column portions 30 can be suppressed when the second electrode 42 is being formed.

### 3.5. Fifth Variation

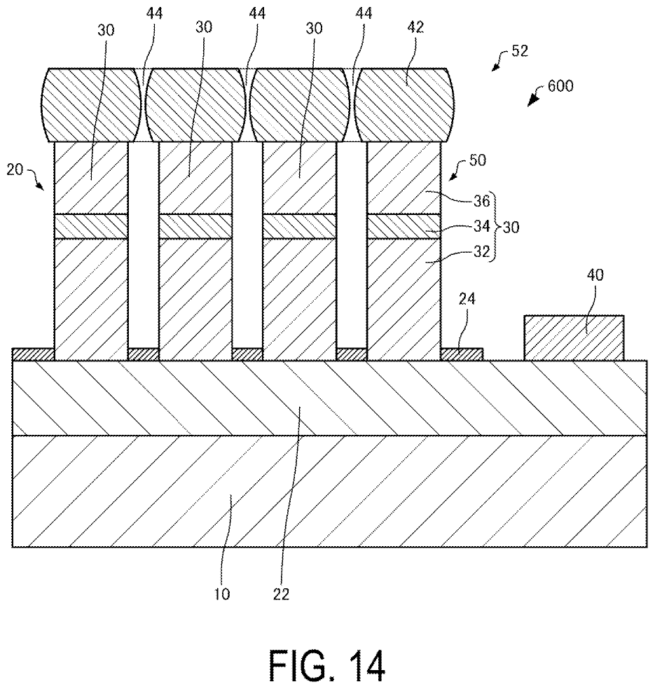

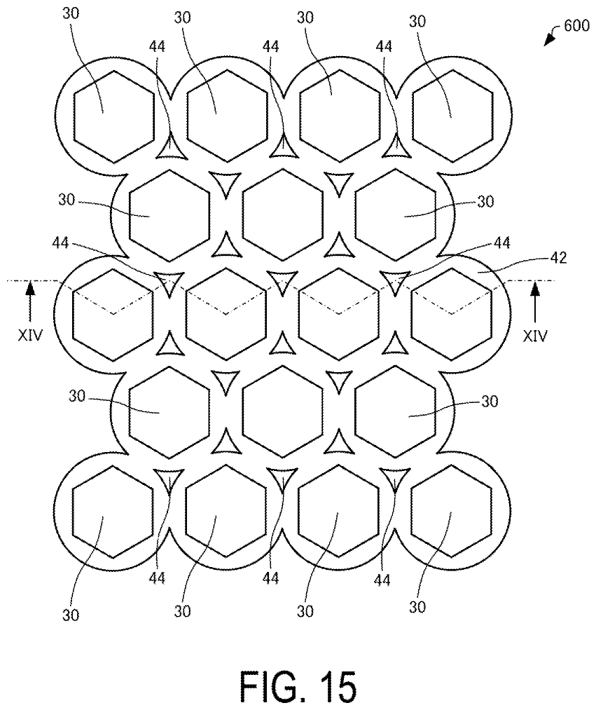

Next, a light-emitting device 600 according to a fifth variation of the present embodiment will be described with reference to drawings. FIG. 14 is a cross-sectional view schematically illustrating the light-emitting device 600 according to the fifth variation of the present embodiment. FIG. 15 is a plan view schematically illustrating column portions 30, a second electrode 42, and first holes 44 according to the light-emitting device 600 of the fifth variation of the present embodiment. Note that FIG. 14 is a cross-sectional view taken along a line XIV-XIV in FIG. 15.

As illustrated in FIG. 1, in the light-emitting device 100, the second electrode 42 has a film shape that is continuous in an in-plane direction. In the light-emitting device 100, the second electrode 42 is patterned to form the first holes 44.

In contrast, in the light-emitting device 600, the first holes 44 are formed without patterning the second electrode 42. In the light-emitting device 600, the second electrode 42 is formed in a condition in which the shape of the column portion 30 is easily inherited as compared to the light-emitting device 100. As a result, growth of the second electrode 42 in an in-plane direction becomes difficult, thus forming the first holes 44 in the second electrode 42, as illustrated in FIG. 14 and FIG. 15. For example, the second electrode 42 can be formed by sputtering, and adjusting the sputtering temperature can form a second electrode 42 of which growth in the in-plane direction is difficult.

In this way, in the light-emitting device 600, the first holes 44 can be formed even without patterning the second electrode 42.

### 3.6. Sixth Variation

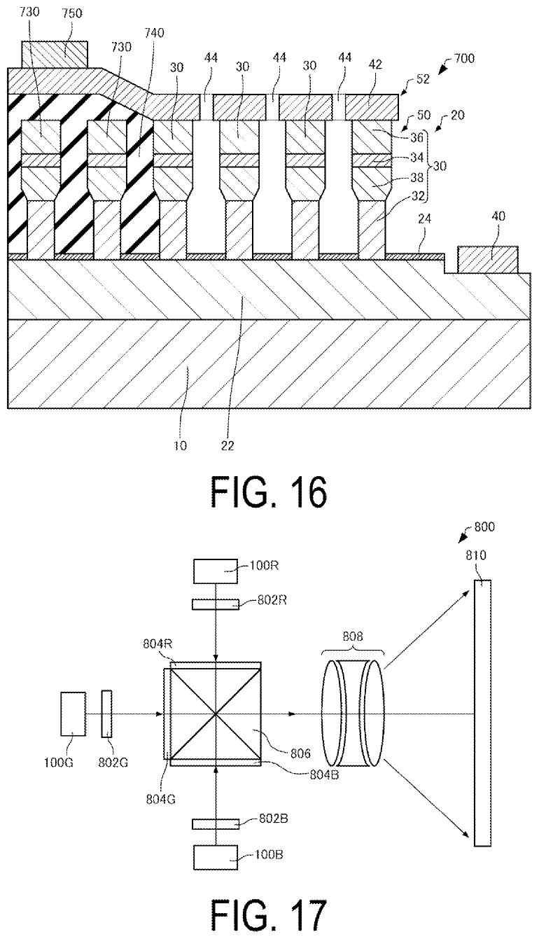

Next, a light-emitting device 700 according to a sixth variation of the present embodiment will be described with reference to drawings. FIG. 16 is a cross-sectional view schematically illustrating the light-emitting device 700 according to the sixth variation of the present embodiment.

As illustrated in FIG. 1, in the light-emitting device 100 described above, the diameter of the first semiconductor layer 32 of the column portion 30 is the same as the diameter of the light-emitting layer 34 of the column portion 30.

In contrast, in the light-emitting device 700, as illustrated in FIG. 16, a diameter of a first semiconductor layer 32 of a column portion 30 is smaller than a diameter of a light-emitting layer 34 of the column portion 30. As a result, compared to a case in which a diameter of the first semiconductor layer 32 of the column portion 30 is the same as a diameter of the light-emitting layer 34 of the column portion 30, the difference between the average refractive index in an in-plane direction in the portion of the light-emitting device 700 with the first semiconductor layer 32 provided and the average refractive index in an in-plane direction in the portion of the light-emitting device 700 with the light-emitting layer 34 provided can be increased. This can increase the optical confinement factor.

In the light-emitting device 700, the column portion 30 includes an optical confinement layer 38. The optical confinement layer 38 is provided on the first semiconductor layer 32. The optical confinement layer 38 is provided between the first semiconductor layer 32 and the light-emitting layer 34. In the illustrated example, the optical confinement layer 38 has a portion in which the diameter of the column portion 30 gradually increases from the first semiconductor layer 32 toward the light-emitting layer 34. The optical confinement layer 38 is composed of, for example, an i-type InGaN layer, or an i-type GaN layer. The In composition of the InGaN layer constituting the optical confinement layer 38 is smaller than the In composition of the InGaN layer constituting the light-emitting layer 34. The optical confinement layer 38 is an OCL that confines light to the light-emitting layer 34.

The light-emitting device 700 includes a dummy column portion 730 spaced apart from the second electrode 42. The dummy column portion 730 does not emit light. The configuration of the dummy column portion 730 is, for example, the same as the configuration of the column portion 30. The dummy column portion 730 is provided in plurality, for example. The dummy column portions 730 are grown in the same steps as those for the column portions 30, for example.

An insulating layer 740 is provided between the dummy column portions 730 and the second electrode 42. The insulating layer 740 surrounds the dummy column portions 730 when viewed from the lamination direction. The insulating layer 740 covers the dummy column portions 730. The insulating layer 740 is provided on a mask layer 24. The insulating layer 740 is, for example, a silicon oxide layer. More specifically, the insulating layer 740 is a SiO₂ layer. The insulating layer 740 is formed by, for example, CVD, or spin-coating.

In the illustrated example, the first electrode 40 is provided in a portion where the buffer layer 22 is partially removed. For example, a portion of the buffer layer 22 is etched, and the first electrode 40 is formed at the etched portion of the buffer layer 22.

An electrode pad 750 is provided on the second electrode 42. The electrode pad 750 overlaps with the dummy column portions 730 when viewed from the lamination direction. The electrode pad 750 contains, for example, titanium, or gold. Wire bonding that is not illustrated, for example, is applied to the electrode pad 750. The electrode pad 750 is formed by, for example, CVD or sputtering.

### 4. Projector

Next, a projector according to the present embodiment will be described with reference to drawings. FIG. 17 is a diagram schematically illustrating a projector 800 according to the present embodiment.

The projector 800 includes, for example, the light-emitting device 100 serving as a light source.

The projector 800 includes a housing that is not illustrated, a red light source 100R that emits red light, a green light source 100G that emits green light, and a blue light source 100B that emits blue light. The red light source 100R, the green light source 100G, and the blue light source 100B are provided in the housing. Note that, for convenience, the red light source 100R, the green light source 100G, and the blue light source 100B illustrated in FIG. 17 are simplified.

The projector 800 further includes, in the housing, a first optical element 802R, a second optical element 802G, a third optical element 802B, a first optical modulation device 804R, a second optical modulation device 804G, a third optical modulation device 804B, and a projection device 808. The first optical modulation device 804R, the second optical modulation device 804G, and the third optical modulation device 804B are, for example, a transmissive liquid crystal light valve. The projection device 808 is, for example, a projection lens.

Light emitted from the red light source 100R is incident on the first optical element 802R. The light emitted from the red light source 100R is condensed by the first optical element 802R. Note that the first optical element 802R may have a function in addition to condensing. The same applies to the second optical element 802G and the third optical element 802B described below.

The light condensed by first optical element 802R is incident on the first optical modulation device 804R. The first optical modulation device 804R modulates the incident light according to information of an image. The projection device 808 then expands an image formed by the first optical modulation device 804R and projects the expanded image to a screen 810.

Light emitted from the green light source 100G is incident on the second optical element 802G. The light emitted from the green light source 100G is condensed by the second optical element 802G.

The light condensed by the second optical element 802G is incident on the second optical modulation device 804G. The second optical modulation device 804G modulates the incident light according to information of an image. The projection device 808 then expands an image formed by the second optical modulation device 804G and projects the expanded image to the screen 810.

Light emitted from the blue light source 100B is incident on the third optical element 802B. The light emitted from the blue light source 100B is condensed by the third optical modulation device 802B.

The light condensed by the third optical element 802B is incident on the third optical modulation device 804B. The third optical modulation device 804B modulates the incident light according to information of an image. The projection device 808 then expands an image formed by the third optical modulation device 804B and projects the expanded image to the screen 810.

In addition, the projector 800 may include a cross dichroic prism 806 that synthesizes the light emitted from the first optical modulation device 804R, the light emitted from the second optical modulation device 804G, and the light emitted from the third optical modulation device 804B and guides the synthesized light to the projection device 808.

Lights of three colors modulated by the first optical modulation device 804R, the second optical modulation device 804G, and the third optical modulation device 804B are incident on the cross dichroic prism 806. The cross dichroic prism 806 is formed by bonding four right-angle prisms together; an inner surface of the cross dichroic prism 806 is provided with a dielectric multilayer film that reflects red light and a dielectric multilayer film that reflects blue light. These dielectric multilayer films synthesize the lights of the three colors to form light expressing a color image. The synthesized light is then projected onto the screen 810 by the projection device 808, and an enlarged image is displayed.

Note that the red light source 100R, the green light source 100G, and the blue light source 100B may directly form an image by controlling the light-emitting device 100 as a pixel of an image according to information of an image; in this scenario, the use of the first optical modulation device 804R, the second optical modulation device 804G, and the third optical modulation device 804B becomes unnecessary. Also, the projection device 808 may enlarge the image formed by the red light source 100R, the green light source 100G, and the blue light source 100B and project the enlarged image to the screen 810.

In addition, in the example described above, a transmissive liquid crystal light valve is used as the optical modulation device, but a light valve other than liquid crystal light valve may be used, or a reflective light valve may be used. Examples of such a light valve include a reflective liquid crystal light valve or a digital micro-mirror device. The configuration of the projection device is changed as appropriate depending on the type of the light valve used.

Further, the light source can be applied to a light source device of a scanning-type image display device having scanning means, the scanning means being an image formation device that displays an image of a desired size on a display surface by scanning light from the light source on a screen.

The light-emitting device according to the embodiment described above can also be used in applications in addition to projectors. Examples of applications in addition to projectors include indoor and outdoor lighting, displays, laser printers, scanners, automotive lights, sensing devices using light, light sources for communication devices, and display devices of head-mounted displays. Further, the light-emitting device according to the embodiment described above can also be applied to light emitting elements of Light Emitting Diode (LED) displays in which tiny light-emitting elements are arranged in an array to display an image.

The embodiment and variations described above are examples and are not serving as limitations. For example, the embodiment and variations can be combined as appropriate.

The present disclosure includes configurations that are substantially the same as a configuration described in an embodiment, such as configurations having the same function, method and result, or configurations having the same object and effect. Furthermore, the present disclosure includes configurations in which a non-essential part of a configuration described in an embodiment is replaced. The present disclosure also includes configurations having the same action and effect as a configuration described in an embodiment or configurations capable of achieving the same object. Further, the present disclosure includes configurations in which a known technology is added to a configuration described in an embodiment.

The following contents are derived from the above-described embodiment and variations.

One aspect of a light-emitting device includes

a substrate,

a laminated structure having a plurality of column portions, and

an electrode provided on a side of the laminated structure opposite to the substrate, wherein

each of the plurality of column portions includes a light-emitting layer,

the electrode is provided with a plurality of first holes,

the plurality of column portions form a first photonic crystal,

the electrode forms a second photonic crystal, and

the first photonic crystal and the second photonic crystal are optically coupled to each other.

According to the light-emitting device, scattering of light generated by the light-emitting layer in the first holes can be reduced.

In one aspect of the light-emitting device, each of the plurality of first holes may extend through the electrode.

According to the light-emitting device, an optical confinement factor can be increased.

In one aspect of the light-emitting device,

each of the plurality of first holes may not overlap with the plurality of column portions when viewed from the vertical direction to the substrate.

According to the light-emitting device, when the first holes are formed by etching, damage to the column portions caused by etching can be suppressed.

In one aspect of the light-emitting device,

each of the plurality of column portions may include:

a first semiconductor layer of a first conductive type, and

a second semiconductor layer of a second conductive type that is different from the first conductive type, wherein

the light-emitting layer may be provided between the first semiconductor layer and the second semiconductor layer,

the first semiconductor layer may be provided between the substrate and the light-emitting layer,

the laminated structure may include a light propagation layer provided between adjacent column portions among the plurality of column portions,

the light propagation layer may be provided with a second hole,

the second hole may be coupled with one of the plurality of first holes, and

a bottom surface of the second hole may be positioned between the second semiconductor layers of adjacent column portions of the plurality of column portions.

According to the light-emitting device, an optical confinement factor can be increased.

In one aspect of the light-emitting device,

each of the plurality of first holes may overlap with the plurality of column portions when viewed from the vertical direction to the substrate.

According to the light-emitting device, an optical confinement factor can be increased.

In one aspect of the light-emitting device,

each of the plurality of first holes may not extend through the electrode.

According to the light-emitting device, damage to the column portions caused by the etching for forming the first holes can be suppressed.

One aspect of a projector includes

one aspect of the light-emitting device.

What is claimed is:

1. A light-emitting device comprising:
a substrate,
a laminated structure having a plurality of column portions, and
an electrode provided on a side of the laminated structure opposite to the substrate, wherein
each of the plurality of column portions includes a light-emitting layer,
the electrode is provided with a plurality of first holes,
the plurality of column portions form a first photonic crystal,
the electrode forms a second photonic crystal, and
the first photonic crystal and the second photonic crystal are optically coupled to each other.

2. The light-emitting device according to claim 1, wherein
each of the plurality of first holes extends through the electrode.

3. The light-emitting device according to claim 2, wherein
each of the plurality of first holes does not overlap with the plurality of column portions when viewed from a vertical direction to the substrate.

4. The light-emitting device according to claim 3, wherein
each of the plurality of column portions comprises:
a first semiconductor layer of a first conductive type, and
a second semiconductor layer of a second conductive type that is different from the first conductive type, wherein
the light-emitting layer is provided between the first semiconductor layer and the second semiconductor layer,
the first semiconductor layer is provided between the substrate and the light-emitting layer,
the laminated structure includes a light propagation layer provided between adjacent column portions among the plurality of column portions,
the light propagation layer is provided with a second hole,
the second hole is coupled with one of the plurality of first holes, and
a bottom surface of the second hole is positioned between the second semiconductor layers of adjacent column portions of the plurality of column portions.

5. The light-emitting device according to claim 1, wherein
each of the plurality of first holes overlaps with the plurality of column portions when viewed from a vertical direction to the substrate.

6. The light-emitting device according to claim 5, wherein
each of the plurality of first holes does not extend through the electrode.

7. A projector comprising the light-emitting device according to claim 1.
